(19) United States
(12) Patent Application Publication
(10) Pub. No.: US 2025/0330170 A1
(43) Pub. Date: Oct. 23, 2025

(54) HIGH-SIDE SWITCH CIRCUIT

(71) Applicant: Texas Instruments Incorporated, Dallas, TX (US)

(72) Inventors: Abdullah AL-OBAIDI, Dallas, TX (US); Sravya KANNEGANTI, Dallas, TX (US)

(73) Assignee: Texas Instruments Incorporated, Dallas, TX (US)

(21) Appl. No.: 18/638,069

(22) Filed: Apr. 17, 2024

(51) Int. Cl. H03K 17/06; H02M 3/07; H03K 17/10

(52) U.S. Cl. CPC H03K 17/0822; H03K 2217/0063

(57) ABSTRACT

A circuit includes an input terminal, an output terminal, a first transistor, a second transistor, a charge pump circuit, and a resistor. The input terminal is configured to provide an input voltage. The output terminal is configured to provide an output voltage. The first transistor has a first terminal coupled to the input terminal, a second terminal coupled to the output terminal, and a control terminal. The charge pump circuit has an output coupled to the control terminal. The resistor has a first terminal coupled to the control terminal, and a second terminal. The second transistor has a first terminal coupled to the second terminal of the resistor, a second terminal coupled to the output terminal, and a control terminal. The current source has an input coupled to the control terminal of the second transistor.

### BACKGROUND

A high-side switch is a switch that is connected between a power supply and a load circuit to control provision of power to the load circuit. The switching device in a high-side switch circuit may be a relay or a semiconductor switching device, such as a transistor. Semiconductors provide a number of advantages over electro-mechanical switches in high-side switching applications. For example, semiconductor switches may reduce the risk of electric spark, reduce circuit area, and reduce cost relative to electro-mechanical switches.

### SUMMARY

In one example, a circuit includes an input terminal, an output terminal, a first transistor, a second transistor, a charge pump circuit, and a resistor. The input terminal is configured to provide an input voltage. The output terminal is configured to provide an output voltage. The first transistor has a first terminal coupled to the input terminal, a second terminal coupled to the output terminal, and a control terminal. The charge pump circuit has an output coupled to the control terminal. The resistor has a first terminal coupled to the control terminal, and a second terminal. The second transistor has a first terminal coupled to the second terminal of the resistor, a second terminal coupled to the output terminal, and a control terminal. The current source has an input coupled to the control terminal of the second transistor.

In another example, a circuit includes an input terminal, an output terminal, a first transistor, a second transistor, a resistor, and a control circuit. The first transistor is configured to conduct a current from the input terminal to the output terminal. The first transistor has a control terminal. The second transistor and the resistor are coupled in series between the control terminal and the output terminal. The second transistor has a control terminal. The control circuit has an output coupled to the control terminal of the second transistor. The control circuit is configured to turn on the second transistor responsive to the current being greater than a threshold, and turn off the second transistor responsive to the current being less than the threshold.

In a further example, a system includes a power source, a high-side switch circuit, and a load circuit. The power source has an output. The high-side switch circuit has a switch input coupled to the output of the power source, and a switch output. The load circuit has an input coupled to the switch output. The high-side switch circuit includes a first transistor, a second transistor, a charge pump circuit, a resistor, a current source, and a switch. The first transistor has a first terminal coupled to the switch input, a second terminal coupled to the switch output, and a control terminal. The charge pump circuit has an output coupled to the control terminal. The resistor has a first terminal coupled to the control terminal, and a second terminal. The second transistor has a first terminal coupled to the second terminal of the resistor, a second terminal coupled to the output terminal, and a control terminal. The current source has an input. The switch is coupled between the control terminal of the second transistor and the input of the current source.

### BRIEF DESCRIPTION OF THE DRAWINGS

FIG. 1 is schematic diagram of an example high-side switch circuit suitable for use in low power applications.

FIG. 2 is a graph of example signals in the high-side switch circuit of FIG. 1.

FIG. 3 is a block diagram of an example system that includes the high-side switch circuit of FIG. 1.

### DETAILED DESCRIPTION

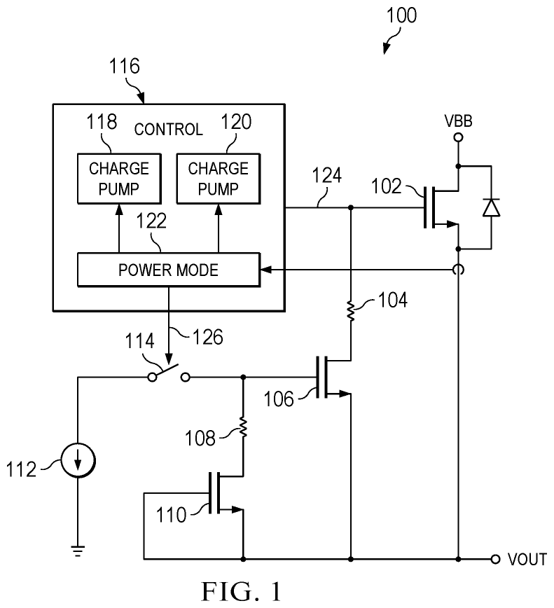

High-side switch circuits can be used to control the provision of power in a variety of applications. However, because high-side switch circuits may consume power even when the load current is very low, use of high-side switch circuits in low-power applications has been limited. FIG. 1 is schematic diagram of an example high-side switch circuit 100 suitable for use in low power applications. The high-side switch circuit 100 includes a transistor 102, a resistor 104, a transistor 106, a resistor 108, a transistor 110, a current source 112, a switch 114, and a control circuit 116. The transistor 102 is a pass transistor that conducts current from an input terminal (VBB) to an output terminal (VOUT). VBB may be coupled to a power source, such as a battery, and VOUT may be coupled to a load circuit that is powered via the high-side switch circuit 100. The transistor 102 may be n-channel field effect transistor (NFET). A first terminal (e.g., drain) of the transistor 102 is coupled to VBB. A second terminal (e.g., source) of the transistor 102 is coupled to VOUT. A control terminal (e.g., gate) of the transistor 102 is coupled to the resistor 104 and the control circuit 116. The control circuit 116 provides a control signal 124 that turns the transistor 102 on or off.

The resistor 104 and the transistor 106 are coupled in series between the control terminal of the transistor 102 and VOUT to reduce the difference in voltage between VOUT and the control terminal of the transistor 102 when the transistor 102 is turned off. As a result, if a transient voltage is present on VOUT, for example, then the connection of VOUT to the control terminal of the transistor 102 can prevent the transistor 102 from turning on in error if the transistor 102 is turned off. However, if the resistor 104 directly connects VOUT to the control terminal of the transistor 102 (e.g., the transistor 106 is not present), then current flow through the resistor 104 to VOUT increases the power consumed by the high-side switch circuit 100, and can make the high-side switch circuit 100 less suitable for use in low power applications. In some implementations of the high-side switch circuit 100, the resistor 104 may have a resistance of about two mega-ohms and the resistor 108 may have a resistance of about 1.25 mega-ohms. The resistors 104 and 108 have different resistance values in some implementations of the high-side switch circuit 100.

In the high-side switch circuit 100, a first terminal of the resistor 104 is coupled to the control terminal of the transistor 102. A second terminal of the resistor 104 is coupled to a first terminal (e.g., drain) of the transistor 106. A second terminal (e.g., source) of the transistor 106 is coupled to VOUT. A control terminal (e.g., gate) of the transistor 106 is coupled to the current source 112 via the switch 114. A first terminal of the switch 114 is coupled to the control terminal of the transistor 106. A second terminal of the switch 114 is coupled to an input of the current source 112. A control input of the switch 114 is coupled to an output of the control circuit 116. An output of the current source 112 is coupled to a reference terminal (e.g., ground).

The control circuit 116 turns on the transistor 106 to connect the control terminal of the transistor 102 to VOUT through the resistor 104, and turns off the transistor 106 to disconnect the control terminal of the transistor 102 from VOUT. The control circuit 116 may turn on the transistor 106 if the current flowing through the transistor 102 is greater than a predetermined threshold (e.g., the high-side switch circuit 100 is operating in a normal mode). The control circuit 116 may turn off the transistor 106 if the current flowing through the transistor 102 is less than the threshold (e.g., the high-side switch circuit 100 is operating in a low power mode). If the transistor 106 is turned off, current flow from the control circuit 116 to VOUT is significantly reduced, which can make the high-side switch circuit 100 suitable for use in low power applications.

The transistor 106 may be a natural transistor (e.g., a natural NFET). Accordingly, the threshold voltage of the transistor 106 may be very low (e.g., a negative threshold voltage, zero volt threshold, etc.), and the transistor 106 may be normally on. If the switch 114 is open, the voltage at the control terminal of the transistor 106 is set by the resistor 108 and transistor 110. The resistor 108 and the transistor 110, coupled in series, pull the control terminal of the transistor 106 to VOUT to turn on the transistor 106. The transistor 110 may be natural NFET. A first terminal of the resistor 108 is coupled to the control terminal of the transistor 106. A second terminal of the resistor 108 is coupled to a first terminal (e.g., drain) of the transistor 110. A second terminal (e.g., source) of the transistor 110 is coupled to VOUT. A control terminal (e.g., gate) of the transistor 110 is also coupled to VOUT. The transistor 110 can prevent current flow from VOUT to the switch 114. The transistor 110 may not be included in some examples of the high-side switch circuit 100.

The control circuit 116 provides a switch control signal 126 to control the switch 114. If the current flow through the transistor 102 is less than the threshold, the control circuit 116 (via the switch control signal 126) closes the switch 114 to turn off the transistor 106. The control circuit 116 provides the switch control signal 126 at an output of the control circuit 116 that is coupled to the control input of the switch 114. The switch control signal 126 closes the switch 114 to pull the control terminal of the transistor 106 well below the voltage on VOUT, which turns off the transistor 106. For example, the current source 112 may pull the control terminal of the transistor 106 to a voltage that is 2 volts, 2.5 volts, 5 volts, etc. less than the voltage at VOUT.

The control circuit 116 includes a charge pump circuit 118, a charge pump circuit 120, and a power mode circuit 122. The power mode circuit 122 measures the current flowing through the transistor 102, and controls the switch 114, the charge pump circuit 118, and the charge pump circuit 120 based on the measured current. For example, the power mode circuit 122 may compare measurements of the current flowing through the transistor 102 to a threshold current. If the current flowing through the transistor 102 is greater than a first threshold current (e.g., 100 milliamperes, 150 milliamperes), the power mode circuit 122 provides control signals to enable (activate) the charge pump circuit 118, disable (deactivate) the charge pump circuit 120, and open the switch 114. If the current flowing through the transistor 102 is less than a second threshold current (e.g., 100 milliamperes, 150 milliamperes) (the high-side switch circuit 100 is in the low power mode), the power mode circuit 122 provides a first charge pump control signal to disable (deactivate) the charge pump circuit 118, provides a second charge pump control signal to enable (activate) the charge pump circuit 120, and the switch control signal to close the switch 114. The first and second threshold currents may be the same or different in various implementations of the high-side switch circuit 100.

The charge pump circuit 118 provides an output voltage to turn on the transistor 102 if the current flow through the transistor 102 is greater than the threshold current. The charge pump circuit 120 provides an output voltage to turn on the transistor 102 if the current flow through the transistor 102 is less than the threshold current. The output voltage provided by the charge pump circuit 118 and the charge pump circuit 120 may be greater than the voltage at VOUT by at least the threshold voltage of the transistor 102. For example, the output voltage provided by the charge pump circuit 118 and the charge pump circuit 120 may be five volts greater than the voltage at VOUT. The charge pump circuit 118 provides sufficient current to turn on the transistor 102 with some current flowing through the resistor 104. The charge pump circuit 120 may provide substantially lower current than the charge pump circuit 118 because in the low power mode no current flows from the charge pump circuit 120 to VOUT through the resistor 104. Accordingly, in operation, the charge pump circuit 120 may consume less power than the charge pump circuit 118, which makes the high-side switch circuit 100 more suitable for use in low power applications.

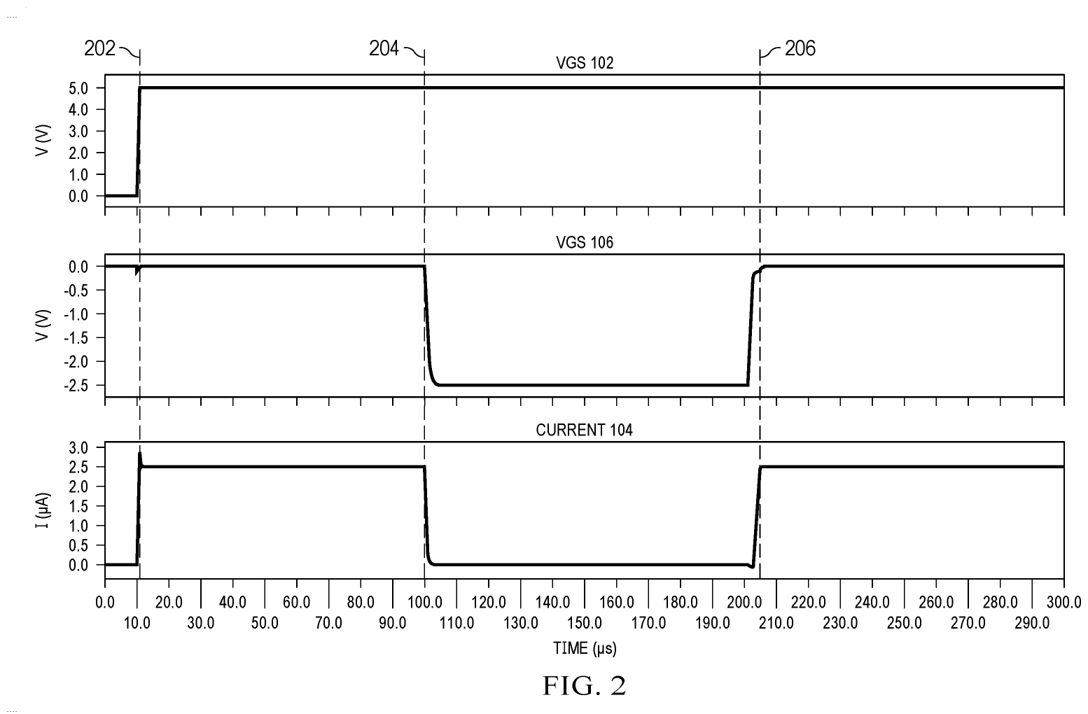

FIG. 2 is a graph of example signals in the high-side switch circuit 100. FIG. 2 shows gate-to-source voltage of the transistor 102 (VGS 102), gate-to-source voltage of the transistor 106 (VGS 106), and current flow in the resistor 104 (CURRENT 104). At time 202, the control circuit 116 generates the control signal 124 to turn on the transistor 102, and VGS 102 increases from 0 volts to 5 volts. The VGS 106 is at about zero volts, and the transistor 106 is on. With the increase in VGS 102, and the transistor 106 turned on, the current flowing through the resistor 104 increases to about 2.5 micro-amperes.

At time 204, the control circuit 116 provides the control signal 126 to close the switch 114. With the switch 114 closed the current source 112 sinks current from the control terminal of the transistor 106, VGS 106 drops to about-2.5 volts, and the transistor 106 turns off. Turning off the transistor 106 reduces the current flowing through the resistor 104 to about 55 pico-amperes.

At time 206, the control circuit 116 provides the control signal 126 to open the switch 114. With the switch 114 open, the VGS 106 increases to about zero volts, the transistor 106 turns on, and the current flowing through the resistor 104 and the transistor 106 increases to about 2.5 micro-amperes. Accordingly, with the transistor 106 turned off, the current flowing through the resistor 104 is significantly lower (e.g., over 4 orders of magnitude lower) than if the transistor 106 is turned on, which makes the high-side switch circuit 100 suitable for use in low-power applications.

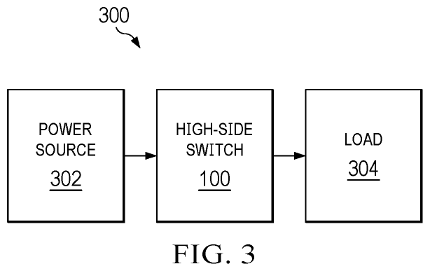

FIG. 3 is a block diagram of an example system 300 that includes the high-side switch circuit 100. The system 300 may be provided in a vehicle, industrial equipment, etc. The system 300 includes a power source 302, the high-side switch circuit 100, and a load circuit 304. The power source 302 may be a battery (e.g., a vehicle battery) in some implementations. The high-side switch circuit 100 is coupled between the power source 302 and the load circuit 304 to control a voltage provided to the load circuit 304. The high-side switch circuit 100 may operate as an electronic fuse that can limit or halt the flow of current to the load circuit 304 if the current exceeds a threshold. In a vehicular application, the load circuit 304 may be any of a variety of circuits. For example, the load circuit 304 may be a vehicle lighting circuit, a vehicle control circuit (e.g., engine control), an advanced driver assistance system, or other vehicle circuit. Because the high-side switch circuit 100 can disconnect the resistor 104 in situations where the current drawn by the load circuit 304 is very low, the high-side switch circuit 100 can be used in vehicular applications. For example, the high-side switch circuit 100 can be used in applications in which the vehicle is turned off (e.g., parked) for an extended period without draining the vehicle's battery.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) (n-type transistor) or a p-channel FET (PFET)) (p-type transistor)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input (or transistor control terminal) is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit comprising:
an input terminal configured to provide an input voltage;
an output terminal configured to provide an output voltage;
a first transistor having a first terminal coupled to the input terminal, a second terminal coupled to the output terminal, and a control terminal;
a charge pump circuit having an output coupled to the control terminal; and
a resistor having a first terminal coupled to the control terminal, and a second terminal;
a second transistor having a first terminal coupled to the second terminal of the resistor, a second terminal coupled to the output terminal, and a control terminal; and
a current source having an input coupled to the control terminal of the second transistor.

2. The circuit of claim 1, wherein the second transistor is a natural transistor.

3. The circuit of claim 1, further comprising a third transistor having a first terminal coupled to the control terminal of the second transistor, a second terminal coupled to the second terminal of the second transistor, and a control terminal coupled to the second terminal of the third transistor.

4. The circuit of claim 3, further comprising a second resistor coupled between the control terminal of the second transistor and the first terminal of the third transistor.

5. The circuit of claim 3, wherein the third transistor is a natural transistor.

6. The circuit of claim 1, further comprising a switch coupled between the input of the current source and control terminal of the second transistor.

7. The circuit of claim 6, wherein:
the charge pump circuit is a first charge pump circuit; and
the circuit includes a second charge pump circuit having an output coupled to the control terminal of the first transistor.

8. The circuit of claim 7, further comprising a control circuit having a first output coupled to the first charge pump circuit, a second output coupled to a control input of the switch, and a third output coupled to the second charge pump circuit, the control circuit configured to:
provide, at the first output, a first charge pump control signal having a first state to enable the first charge pump circuit for operation of the circuit in a first mode;
provide, at the second output, a switch control signal, having a second state to open the switch for operation of the circuit in the first mode;
provide, at the third output, a second charge pump control signal, having a second state to disable the second charge pump circuit for operation of the circuit in the first mode;
provide, at the first output, the first charge pump control signal having the second state to disable the first charge pump circuit for operation of the circuit in a second mode;
provide, at the second output, the switch control signal, having the first state to close the switch for operation of the circuit in the second mode; and
provide, at the third output, the second charge pump control signal, having the first state to enable the second charge pump circuit for operation of the circuit in the second mode.

9. A circuit comprising:
an input terminal and an output terminal;
a first transistor configured to conduct a current from the input terminal to the output terminal, the first transistor having a control terminal;
a second transistor and a resistor coupled in series between the control terminal and the output terminal, the second transistor having a control terminal;
a control circuit having an output coupled to the control terminal of the second transistor, the control circuit configured to:
turn on the second transistor responsive to the current being greater than a threshold; and
turn off the second transistor responsive to the current being less than the threshold.

10. The circuit of claim 9, further comprising a current source having an input coupled to the control terminal of the second transistor, the current source configured to provide a voltage at the control terminal of the second transistor that is less than a voltage at the output terminal.

11. The circuit of claim 10, further comprising a switch coupled between the input of the current source and the control terminal of the second transistor, the switch having a control input coupled to the output of the control circuit; and the switch configured to pass current from the control terminal of the second transistor responsive to the current being less than the threshold.

12. The circuit of claim 9, wherein the second transistor is a natural transistor.

13. The circuit of claim 9, further comprising a third transistor coupled between the control terminal of the second transistor and the output terminal, the third transistor having a control terminal coupled to the output terminal.

14. The circuit of claim 13, further comprising a resistor coupled between the control terminal of the second transistor and third transistor.

15. The circuit of claim 13, wherein the third transistor is a natural transistor.

16. The circuit of claim 9 wherein the control circuit includes:
a first charge pump circuit having an output coupled to the control terminal of the first transistor, the first charge pump circuit configured to provide a control signal responsive to the current being greater than the threshold; and
a second charge pump circuit having an output coupled to the control terminal of the first transistor, the second charge pump circuit configured to provide the control signal responsive to the current being less than the threshold.

17. A system comprising:
a power source having an output;
a high-side switch circuit having a switch input coupled to the output of the power source, and a switch output; and
a load circuit having an input coupled to the switch output;
wherein the high-side switch circuit includes:
a first transistor having a first terminal coupled to the switch input, a second terminal coupled to the switch output, and a control terminal;
a charge pump circuit having an output coupled to the control terminal; and
a resistor having a first terminal coupled to the control terminal, and a second terminal;
a second transistor having a first terminal coupled to the second terminal of the resistor, a second terminal coupled to the switch output, and a control terminal;
a current source having an input; and
a switch coupled between the control terminal of the second transistor and the input of the current source.

18. The system of claim 17, wherein
the resistor is a first resistor; and
the high-side switch circuit includes:
a third transistor having a first terminal, a second terminal coupled to the second terminal of the second transistor, and a control terminal coupled to the second terminal of the third transistor; and
a second resistor coupled between the control terminal of the second resistor and the first terminal of the third transistor.

19. The system of claim 18, wherein the second transistor and the third transistor are natural transistors.

20. The system of claim 17, wherein:
the charge pump circuit is a first charge pump circuit; and
the high-side switch circuit includes:
a second charge pump circuit; and
a control circuit configured to:
activate the first charge pump circuit responsive to a current flowing through the first transistor that is greater than a threshold; and
activate the second charge pump circuit responsive to a current flowing through the first transistor that is less than the threshold.
